(19) United States
(12) Patent Application Publication
(10) Pub. No.: US 2018/0083619 A1
(43) Pub. Date: Mar. 22, 2018

(54) LIGHT CONTROL TYPE KEY SWITCH ASSEMBLY

(71) Applicant: SOLID YEAR CO., LTD., NEW TAIPEI CITY (TW)

(72) Inventors: Chao-Yang HOU, NEW TAIPEI CITY (TW); Tien-Hao YANG, KEELUNG CITY (TW)

(21) Appl. No.: 15/682,074

(22) Filed: Aug. 21, 2017

(30) Foreign Application Priority Data
Sep. 22, 2016 (TW) 105214528

(51) Int. Cl. H03K 17/969; H01H 13/70

(52) U.S. Cl. CPC H03K 17/969; H03K 2217/94112; H03K 2217/94102; H01H 13/70

(57) ABSTRACT

A light control type key switch assembly includes multiple key switch units each including a key switch holder and a key switch mounted in the key switch holder, multiple light receivers respectively mounted around one respective key switch holder, and a light-emitting unit including a light source and a light guide facing toward the light source and neighbored to each key switch holder for guiding the emitted light from the light source along a light path toward each light receiver. When the key switch is not pressed, the plunger of the respective key switch is kept away from the light path, and thus no electrical signal will be generated. When the key switch is pressed, the plunger of the respective key switch enters the light path, causing an electrical signal output.

### BACKGROUND OF THE INVENTION

### 1. Field of the Invention

The present invention relates to key switch technology and more particularly, to a light control type key switch assembly, which uses one single light source to achieve electrical signal output.

### 2. Description of the Related Art

In conventional keyboards, in addition to utilizing the mutual contact between two metal shrapnels to produce an electrical signal, there is also a technique that uses the light blocking to complete the electrical signal output. In simple terms, when the key switch is pressed, the light emitted by the light source inside the key switch can be successfully received by the light receiver, and the electrical signal will be generated immediately. Once the pressure on the key switch is released, the light receiver will not receive the light from the light source, and there will be no electrical signal generation.

However, in the aforementioned prior art technology, each key switch maters with one respective light source, so the entire keyboard will need a very large number of light sources, complicating the structural arrangement and increasing the manufacturing cost, and therefore, it is necessary to improve the conventional technique.

### SUMMARY OF THE INVENTION

The present invention has been accomplished under the circumstances in view. It is the main object of the present invention to provide a light control type key switch assembly, which uses one single light source to achieve electrical signal output, simplifying the structure and reducing the costs.

To achieve this and other objects of the present invention, a light control type key switch assembly comprises a plurality of key switch units, a plurality of light receivers and a light-emitting unit. The key switch units are arranged in parallel, each comprising a key switch holder, a key switch and a return spring. The key switch holder comprises an axial hole. The key switch comprises a key cap and a plunger. The plunger is connected to the key cap and vertically movably mounted in the axial hole of the key switch holder for allowing key switch to be alternatively moved up and down relative to the key switch holder between an initial position and a pressed position. The return spring is mounted between the key switch holder and the key switch to support the key switch in the initial position. The number of the light receivers is equal to the number of the key switch units. Each light receiver is neighbored to one respective key switch holder. The light-emitting unit comprises a light source and a light guide. The light source is disposed at one side relative to the key switch units, and adapted for emitting light. The light guide is disposed to face toward the light source and neighbored to the key switch holders of the key switch units for guiding the light emitted by the light source along a predetermined light path to the light receivers. When the key switch is disposed in the initial position, the plunger of the respective key switch is kept apart from the light path. When the key switch is disposed in the pressed position, the plunger of the respective key switch enters the light path, causing generation of an electrical signal.

In one embodiment of the present invention, the plungers of the key switches are made of an opaque material, each comprising a light barrier block at a bottom side thereof. The width of the light barrier block remains constant along the axial direction of the respective plunger. Thus, the process for generating an electrical signal by blocking the light will be a clear switching process.

In one embodiment of the present invention, the plungers of the key switches are made of an opaque material, each comprising a light barrier block at a bottom side thereof. The width of the light barrier block gradually reduces along the axis of the respective plunger in direction away from the associating key cap. Thus, the process for generating an electrical signal by blocking the light will be a gradual process, so that the electrical signal can be processed for multi-step mode applications.

In one embodiment of the present invention, the plungers of the key switches are made of a light transmissive material, each comprising a refracting portion so configured that when the respective said key switch is disposed in the pressed position, the respective refracting portion regulates the luminous flux of the light guided by the light guide, so that the electrical signal thus generated can be processed for multi-step mode applications.

In one embodiment of the present invention, the plungers of the key switches are made of an opaque material, each comprising a reflecting surface so configured that when the respective key switch is disposed in the pressed position, the reflecting surface reflects regulates the light guided by the light guide onto the respective light receiver, so that the final electrical signal generation is a clear switching process.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is an oblique top elevational view of a light control type key switch assembly in accordance with a first embodiment of the present invention, illustrating a plurality of key switch units arranged in a row.

FIG. 2 is an upside down view of the light control type key switch assembly shown in FIG. 1 with the circuit board omitted.

FIG. 3 is an oblique top elevational view of an alternate form of the first embodiment of the present invention, illustrating a plurality of key switch units arranged in two rows.

FIG. 4 is an upside down view of the light control type key switch assembly shown in FIG. 3 with the circuit board omitted.

FIG. 5 is a sectional view of a part of the first embodiment of the present invention, illustrating the key switch in the initial position.

FIG. 6 is similar to FIG. 5, illustrating the key switch in the pressed position.

FIG. 7 is a sectional view of a part of a light control type key switch assembly in accordance with a second embodiment of the present invention, illustrating the key switch in the initial position.

FIG. 8 is similar to FIG. 7, illustrating the key switch in the pressed position.

FIG. 9 is an oblique top elevational view of a light control type key switch assembly in accordance with a third embodiment of the present invention.

FIG. 10 is a sectional view of a part of the third embodiment of the present invention, illustrating the key switch in the initial position.

FIG. 11 is similar to FIG. 10, illustrating the key switch in the pressed position.

FIG. 12 is a sectional view of another part of the light control type key switch assembly in accordance with the third embodiment of the present invention, illustrating the key switch in the pressed position.

FIG. 13 is a partial sectional view of a light control type key switch assembly in accordance with a fourth embodiment of the present invention.

FIG. 14 is a partial sectional view of a light control type key switch assembly in accordance with a fifth embodiment of the present invention.

### DETAILED DESCRIPTION OF THE INVENTION

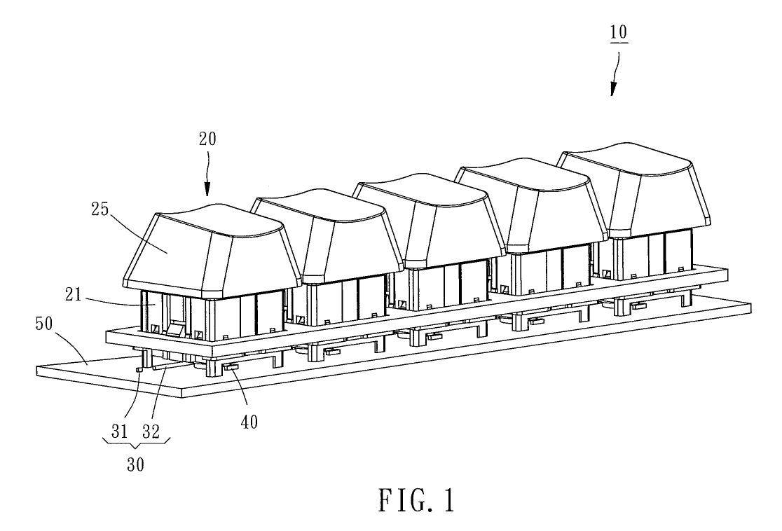

Referring to FIGS. 1-4, a light control type key switch assembly 10 in accordance with the present invention is shown. The light control type key switch assembly 10 comprises a plurality of key switch units 20, a light-emitting unit 30, a plurality of light receivers 40, and a circuit board 50.

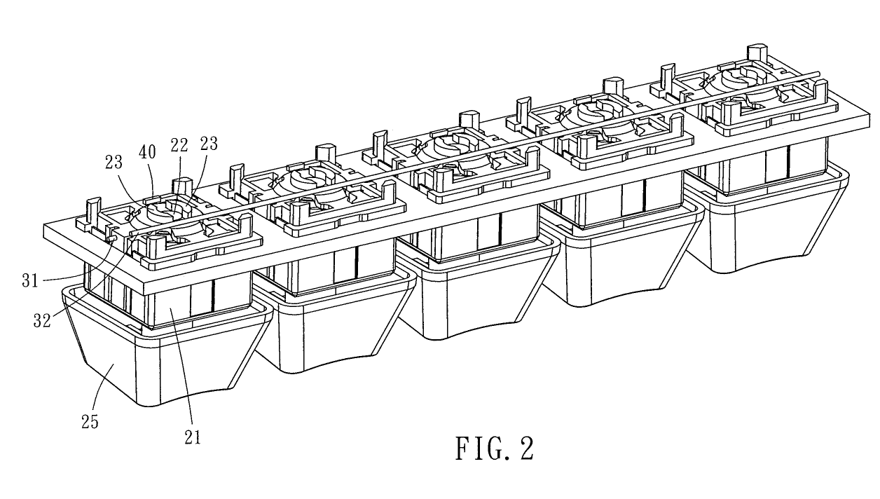

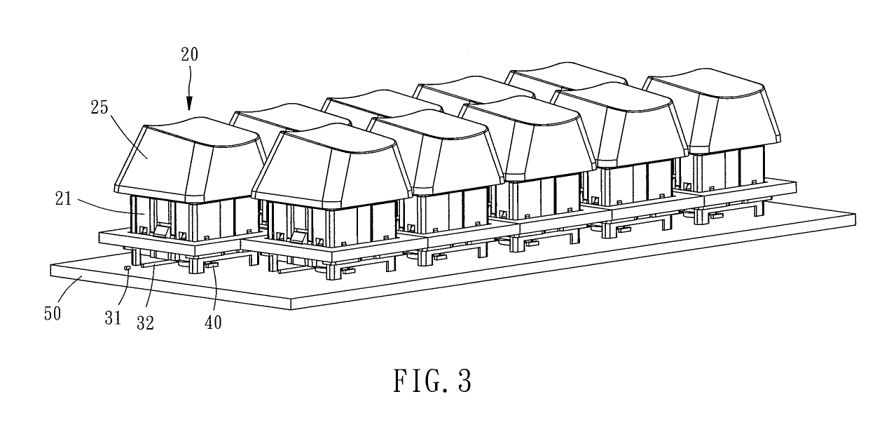

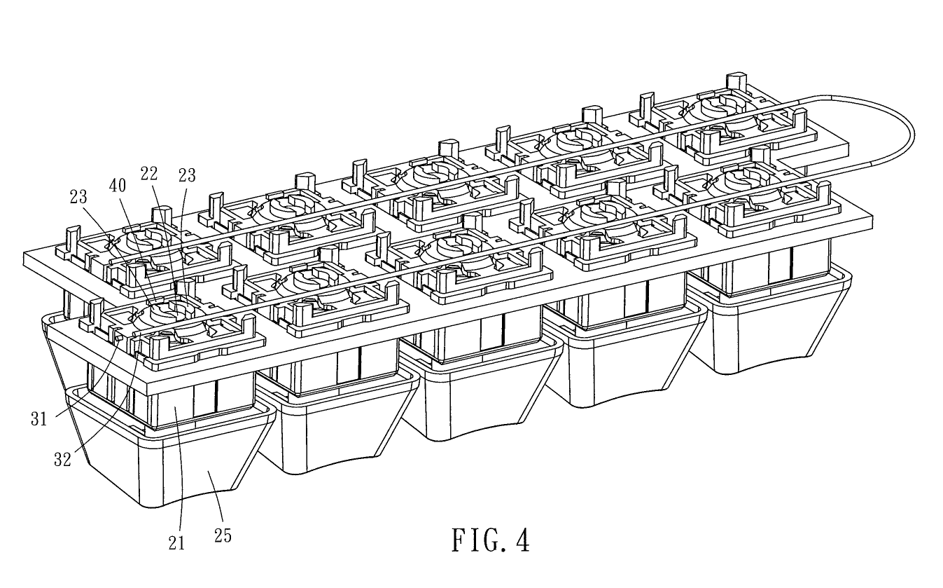

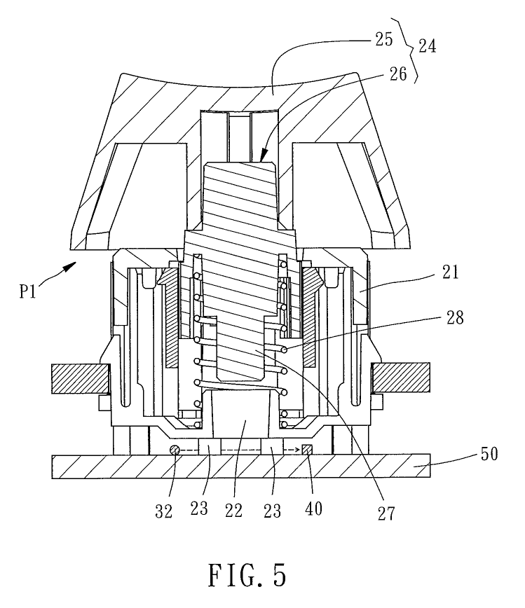

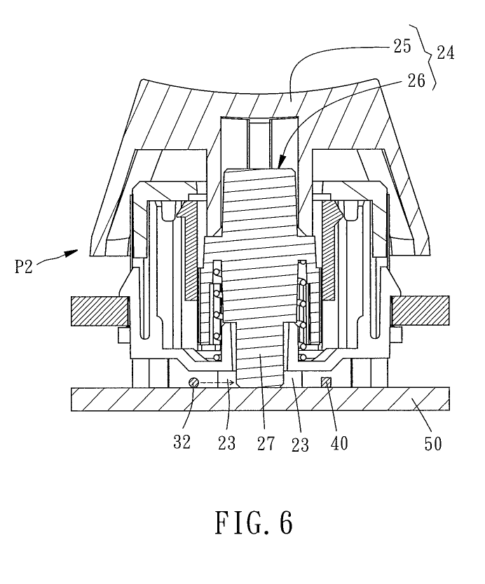

The key switch units 20 are arranged in a row (see FIGS. 1 and 2) or two rows (see FIGS. 3 and 4) in a parallel manner. Referring also to FIG. 5, each key switch unit 20 comprises a key switch holder 21, a key switch 24 and a return spring 28. The key switch holder 21 comprises an axial hole 22, and two opposing light transmissive portions 23 located on a bottom side thereof around the axial hole 22. The key switch 24 comprises a key cap 25 and a plunger 26. The plunger 26 is vertically movably mounted in the axial hole 22 of the key switch holder 21, having a top end thereof connected to a bottom side of the key cap 25 and an opposing bottom end thereof terminating in a light barrier block 27. Thus, the key switch 24 is vertically movable relative to the key switch holder 21 between an initial position P1 (see FIG. 5) and a pressed position P2 (see FIG. 6). Further, the return spring 28 is mounted between the key switch holder 21 and the plunger 26 of the key switch 24, and adapted for imparting an elastically restoring energy to keep the key switch 24 in the initial position P1 shown in FIG. 5.

The number of the light receivers 40 is equal to the number of the key switch units 20. Each light receiver 40 is mounted at the bottom side of the key switch holder 21 of one respect key switch unit 20.

The light-emitting unit 30 comprises a light source 31 and a light guide 32. As illustrated in FIGS. 1-4, the light source 31 is mounted at one side relative to the key switch units 20. The light guide 32 is a strip-shaped member mounted at the bottom side of the key switch holder 21 of each of the key switch units 20, and disposed at one lateral side relative to the plungers 26 of the key switches 24 of the key switch units 20 opposite to the light receiver 40. The light guide 32 has one end thereof facing toward the light source 31 so that the emitted light of the light source 31 can go through a light path into the light receiver 40.

The circuit board 50 is mounted at the bottom side of the key switch holders 21 of the key switch units 29 to carry the light guide 32 and every light receiver 40, and electrically connected with the light receivers 40.

Thus, when the key switch 24 is not pressed by an external pressure and disposed in the initial position P1, the plunger 26 of the key switch 24 is positioned in the axial hole 22 of the associating key switch holder 21, at this time, the light barrier block 27 of the plunger 26 of the key switch 24 is kept apart from the light path, allowing the respective light receiver 40 to receive light from the light guide 32 through the light transmissive portions 23 of the respective key switch holder 21. At this time, no electrical signal is generated. When the key switch 24 is pressed by an external pressure to move from the initial position P1 to the pressed position P2 shown in FIG. 6, the light barrier block 27 of the plunger 26 of the key switch 24 is moved out of the axial hole 22 of the associating key switch holder 21 into the light path, prohibiting the respective light receiver 40 from receiving light from the light guide 32 through the light transmissive portions 23 of the respective key switch holder 21. At this time, the light receiver 40 transmits an optical signal to the circuit board 50, causing the circuit board 50 to convert the optical signal into an electrical signal for output.

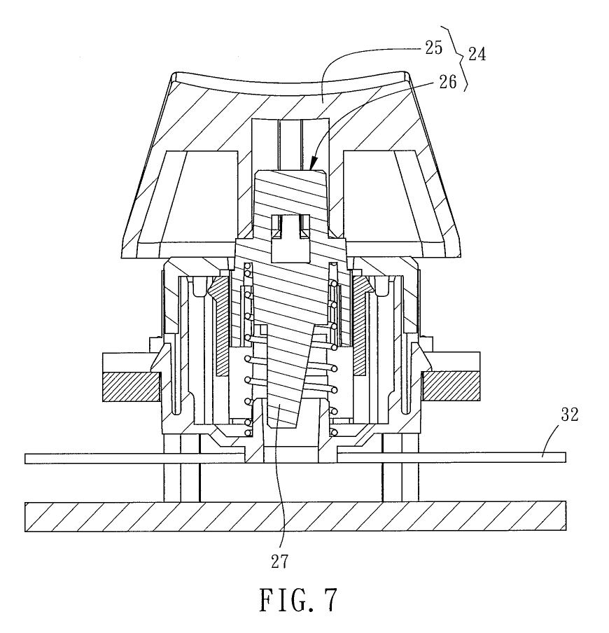

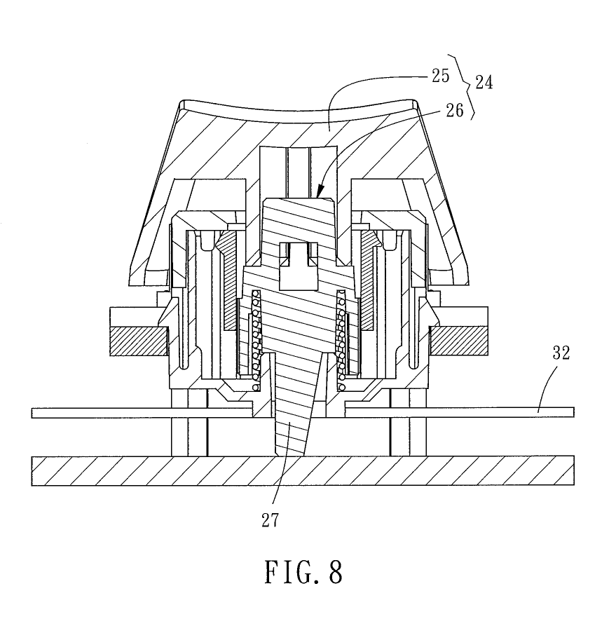

It is necessary to add that the plunger 26 is moved downward to block light when the key cap 25 is pressed by an external pressure, allowing generally of an electrical signal. The plunger 26 can be selectively made of an opaque material or a light transmissive material. In the case that the plunger 26 is made of an opaque material, the width of the light barrier block 27 can be maintained equal to the width of the plunger 26 without change, or gradually increased from the plunger 26 in the direction away from the key cap 25. If the width is maintained constant, as shown in FIGS. 5 and 6, the process for generating an electrical signal by blocking the light will be a clear switching process. If the width of the light barrier block 27 is gradually increased from the plunger 26 in the direction away from the key cap 25, as shown in FIGS. 7 and 8, the process for generating an electrical signal by blocking the light will be a gradual process, so that the electrical signal can be processed for multi-step mode applications.

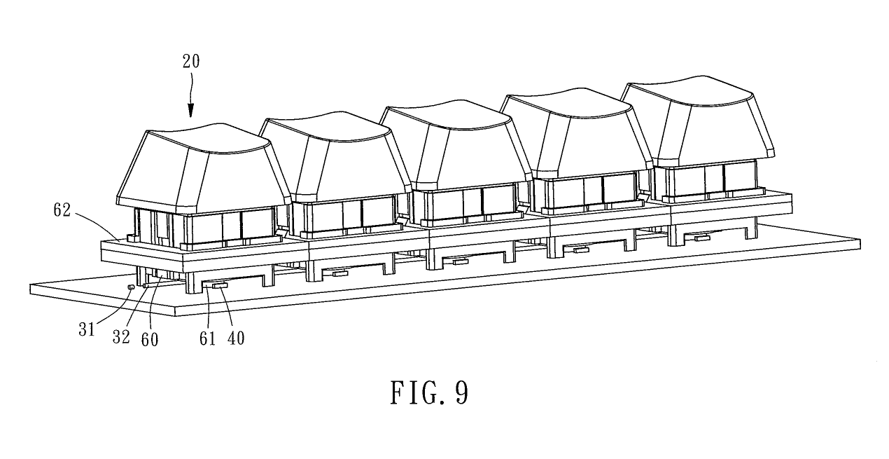

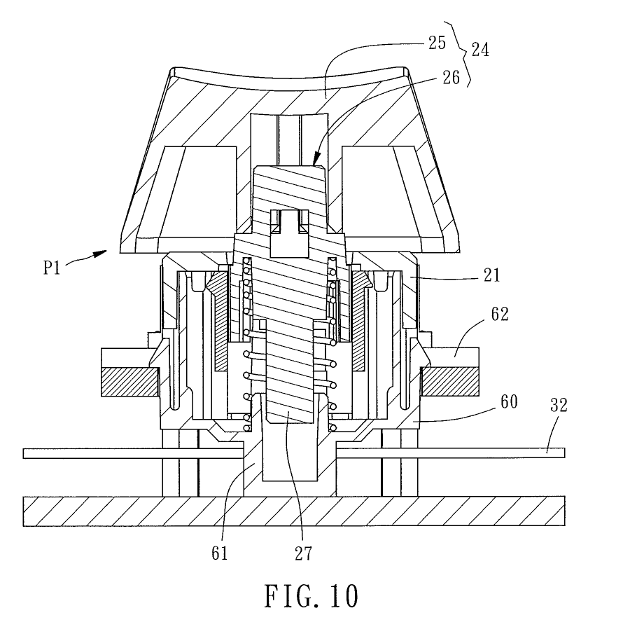

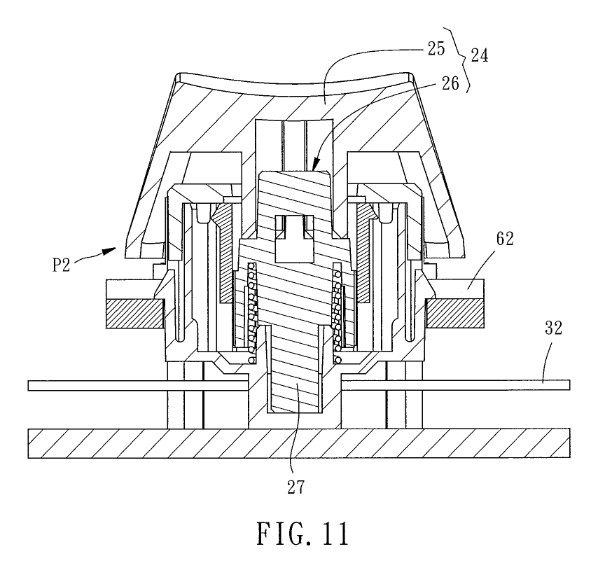

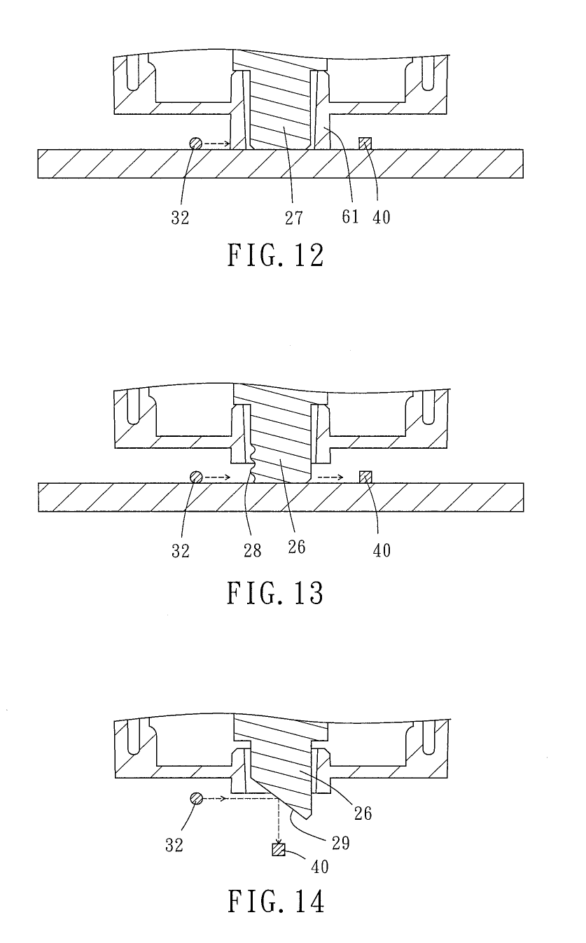

Referring to FIGS. 9-12, in a third embodiment of the present invention, each key switch unit 20 provides a transparent sealing cover 60. The transparent sealing cover 60 is mounted at the bottom side of the key switch holder 21, comprising an axle bush 61. The axle bush 61 is attached onto the light barrier block 27 of the plunger 26 to prohibit external moisture from passing through the bottom side of the key switch holder 21 into the inside of the key switch holder 21 to affect the functioning of the key switch 24. Thus, when the key switch 24 is in the initial position P1 shown in FIG. 10, the light receiver 40 can receive light from the light guide 32 through the axle bush 61 of the transparent sealing cover 60; when the key switch 24 is in the pressed position P2 shown in FIGS. 11 and 12, the light receiver 40 is blocked by the light barrier block 27 of the plunger 26 of the key switch 24 from receiving light from the light guide 32. Each key switch unit 20 further comprises a waterproof gasket 62 covered over the outer periphery so that the key switch holder 21 can further achieve a good waterproof effect.

On the other hand, in a fourth embodiment of the present invention, as illustrated in FIG. 13, the plunger 26 of the key switch 24 is made of a light transmissive material, comprising a refracting portion 28. The refracting portion 28 can be a zigzag structure, satin structure or sandblasted structure. When light passes through the refracting portion 28, the luminous flux will be adjusted, so that the finally generated electrical signal can be processed for multi-step mode applications.

Further, in addition to the use of blocking and refracting techniques, if the light guide 32 and the light receivers 40 are not disposed at two opposite lateral sides relative to the plungers 26 of the key switches 24 but with the light guide 32 (or the light receivers 40) disposed at one lateral side relative to the plungers 26 of the key switches 24 and the light receivers 40 (or the light guide 32) disposed at a bottom side relative to the plungers 26 of the key switches 24, as illustrated in FIG. 14, in this case, the plungers 26 can be made of an opaque material and configured to provide a reflecting surface 29, thus, when the key switch 24 is in the pressed position P2, the light source emitted light will be reflected by the reflecting surface 29 onto the light receiver 40 to further generate an electrical signal.

In conclusion, the light control type key switch assembly 10 of the present invention uses one single light source 31 to emit light and one single light guide 32 to guide the light source emitted light toward multiple light receivers 40 for generating electrical signals, saving light source amount, simplifying the structure and reducing the costs.

What is claimed is:

1. A light control type key switch assembly, comprising:
a plurality of key switch units arranged in parallel, each said key switch unit comprising a key switch holder, a key switch and a return spring, said key switch holder comprising an axial hole, said key switch comprising a key cap and a plunger, said plunger being connected to said key cap and vertically movably mounted in said axial hole of said key switch holder for allowing said key switch to be alternatively moved up and down relative to said key switch holder between an initial position and a pressed position, said return spring being mounted between said key switch holder and said key switch to support said key switch in said initial position;
a plurality of light receivers, the number of said light receivers being equal to the number of said key switch units, each said light receiver being neighbored to one respective said key switch holder; and
a light-emitting unit comprising a light source and a light guide, said light source being disposed at one side relative to said key switch units and adapted for emitting light, said light guide being disposed to face toward said light source and neighbored to said key switch holders of said key switch units for guiding the light emitted by said light source along a predetermined light path to said light receivers;
wherein when the said key switch is disposed in said initial position, the said plunger of the respective said key switch is kept apart from said light path; when the said key switch is disposed in said pressed position, the said plunger of the respective said key switch enters said light path.

2. The light control type key switch assembly as claimed in claim 1, wherein said plungers of said key switches are made of an opaque material, each comprising a light barrier block at a bottom side thereof, the width of said light barrier block remaining constant along the axial direction of the respective said plunger.

3. The light control type key switch assembly as claimed in claim 1, wherein said plungers of said key switches are made of an opaque material, each comprising a light barrier block at a bottom side thereof, the width of said light barrier block gradually reducing along the axis of the respective said plunger in direction away from the associating said key cap.

4. The light control type key switch assembly as claimed in claim 1, wherein the said key switch holder of each said key switch comprises a light transmissive portion at a bottom side thereof, said light transmissive portion being disposed between said light guide and the respective said light receiver so that when the respective said key switch is disposed in said initial position, the respective said light receiver receives the light from said light guide through the respective said light transmissive portion.

5. The light control type key switch assembly as claimed in claim 1, further comprising a circuit board disposed at a bottom side relative to the said key switch holders of said key switch units to carry said light guide and said light receivers, said circuit board being electrically connected with said light receivers.

6. The light control type key switch assembly as claimed in claim 1, wherein each said key switch unit further comprises a transparent sealing cover and a waterproof gasket, said transparent sealing cover being mounted at a bottom side of the associating said key switch holder and comprising an axle bush, said axle bush being attached onto the associating said plunger, said waterproof gasket being covered over an outer perimeter of the associating said transparent sealing cover.

7. The light control type key switch assembly as claimed in claim 1, wherein said plungers of said key switches are made of a light transmissive material, each comprising a refracting portion so configured that when the respective said key switch is disposed in said pressed position, the respective refracting portion regulates the luminous flux of the light guided by said light guide.

8. The light control type key switch assembly as claimed in claim 7, wherein said refracting portion is selectively configured to provide a zigzag structure, a satin structure, or a sandblasted structure.

9. The light control type key switch assembly as claimed in claim 1, wherein said plungers of said key switches are made of an opaque material, each comprising a reflecting surface so configured that when the respective said key switch is disposed in said pressed position, said reflecting surface reflects regulates the light guided by said light guide onto the respective said light receiver.
